(19) United States
(12) Patent Application Publication
(10) Pub. No.: US 2024/0389398 A1
(43) Pub. Date: Nov. 21, 2024

(54) DISPLAY DEVICE AND METHOD FOR FABRICATING THE SAME

(71) Applicant: Samsung Display Co., Ltd., Yongin-si (KR)

(72) Inventors: Do Yeong PARK, Yongin-si (KR); Kyung Bae KIM, Yongin-si (KR)

(21) Appl. No.: 18/616,971

(22) Filed: Mar. 26, 2024

(30) Foreign Application Priority Data
May 16, 2023 (KR) 10-2023-0062799

(51) Int. Cl. H10K 59/122; H10K 59/126; H10K 59/131; H10K 59/38; H10K 59/80

(52) U.S. Cl. CPC H10K 59/122; H10K 59/126; H10K 59/131; H10K 59/38; H10K 59/879

(57) ABSTRACT

A display device includes: a pixel electrode; a bank on the pixel electrode; and a separator on the bank. The separator has a wide width portion having a first tip and a second tip at both sides and a narrow width portion having a third tip on one side.

### CROSS-REFERENCE TO RELATED APPLICATION

This application claims priority from Korean Patent Application No. 10-2023-0062799, filed on May 16, 2023, in the Korean Intellectual Property Office, the entire content of which is incorporated herein by reference.

### BACKGROUND

### 1. Field

Aspects of embodiments of the present disclosure relate to a display device and a method for fabricating the display device.

### 2. Description of Related Art

A width of a back for defining a light emission area in a fine pixel structure is relatively small. Therefore, a lateral leakage current between adjacent pixels may occur, deteriorating picture quality of the display device.

### SUMMARY

Embodiments of the present disclosure provide a display device that may minimize a lateral leakage current between adjacent pixels and minimize a voltage drop.

The aspects and features of the present disclosure are not limited to those mentioned above and additional aspects and features of the present disclosure, which are not mentioned herein, will be clearly understood by those skilled in the art from the following description of the present disclosure.

According to an embodiment of the present disclosure, a display device includes: a pixel electrode; a bank on the pixel electrode; and a separator on the bank. The separator has a wide width portion having a first tip and a second tip on both sides and a narrow width portion having a third tip on one side.

A first angle between a lower surface of the wide width portion and a first side of the wide width portion may be the same as or different from a second angle between the lower surface of the wide width portion and a second side of the wide width portion.

Each of the first angle and the second angle may be an acute angle.

A third angle between a lower surface of the narrow width portion and a first side of the narrow width portion may be different from a fourth angle between the lower surface of the narrow width portion and a second side of the narrow width portion.

The first side from among the first and second sides of the narrow width portion may be farther from the third tip than the second side of the narrow width portion.

The third angle may be smaller than the fourth angle.

The third angle may be smaller than at least one of the first angle and the second angle.

The fourth angle may be the same as at least one of the first angle and the second angle.

Each of the third angle and the fourth angle may be an acute angle.

The separator may include: a support layer on the bank; and a protrusion layer on the support layer.

An upper surface of the support layer of the narrow width portion may be smaller than an upper surface of the support layer of the wide width portion.

The protrusion layer of the narrow width portion may be smaller than the protrusion layer of the wide width portion.

The display device may further include: a light emitting layer on the pixel electrode; and a common electrode on the light emitting layer.

The light emitting layer may include a plurality of light emitting units configured to emit light of different colors.

The light emitting layer may include: a first light emitting unit on the pixel electrode and configured to emit light of a first color; a second light emitting unit on the first light emitting unit and configured to emit light of a second color; and a third light emitting unit on the second light emitting unit and configured to emit light of a third color.

The common electrode may include: a first common electrode on the light emitting layer; and a second common electrode on the first common electrode.

The first common electrode may include: a first sub-common electrode on a light emission area of the pixel electrode; and a second sub-common electrode on the separator.

The first common electrode may further include a connection electrode corresponding to the narrow width portion and connecting the first sub-common electrode with the second sub-common electrode.

The second common electrode may be connected to the second sub-common electrode.

The display device may further include a planarization layer between the first sub-common electrode and the second common electrode and between the connection electrode and the second common electrode.

Details of the other embodiments are included in the detailed description and drawings.

In the display device according to embodiments of the present disclosure, a separator has a wide width portion and a narrow width portion having different gradients and a different number of tips such that a light emitting layer and a charge generation layer are separated for each pixel while a common electrode is not separated. Therefore, a lateral leakage current between adjacent pixels may be reduced or minimized and a voltage drop of a common voltage may be reduced or minimized.

The aspects and features according to embodiments of the present disclosure are not limited to those mentioned above and more, various aspects and features are included in the following description of the present disclosure.

### BRIEF DESCRIPTION OF THE DRAWINGS

The above and other aspects and features of the present disclosure will become more apparent by describing, in detail, embodiments thereof with reference to the attached drawings, in which:

FIG. 1 is a schematic plan view of an electronic device according to an embodiment;

FIG. 2 is a perspective view of a display device included in the electronic device shown in FIG. 1;

FIG. 3 is a cross-sectional view of the display device shown in FIG. 2;

FIG. 4 is a plan view of a display layer of the display device according to an embodiment;

FIG. 5 is a plan view of a pixel electrode and a separator of the display device according to an embodiment;

FIG. 6 is an enlarged perspective view of the portion A in FIG. 5;

FIG. 7 is a cross-sectional view taken along the line I-I′ of FIG. 6;

FIG. 8 is a cross-sectional view taken along the line II-II′ of FIG. 6;

FIG. 9 is a plan view of a pixel electrode, a separator, and a first common electrode of the display device according to another embodiment;

FIG. 10 is a plan view of a first common electrode shown in FIG. 9;

FIG. 11 is a plan view of a first common electrode and a second common electrode of the display device according to another embodiment;

FIG. 12 is a cross-sectional view taken along the line III-III′ in FIGS. 10 and 11;

FIG. 13 is a cross-sectional view of a wide width portion and a peripheral portion of a separator shown in FIG. 12;

FIG. 14 is a cross-sectional view of a wide width portion and a peripheral portion of a separator shown in FIG. 12;

FIG. 15 is a plan view of a pixel electrode and a separator of the display device according to another embodiment;

FIG. 16 is a plan view of a pixel electrode and a separator of the display device according to another embodiment; and

FIGS. 17 to 20 are cross-sectional views of steps of a method for fabricating a display device according to an embodiment.

### DETAILED DESCRIPTION

Aspects and features of the present disclosure and methods of achieving the same will become apparent with reference to embodiments thereof, described below in detail in conjunction with the accompanying drawings. However, the present disclosure is not limited to the embodiments described below and may be implemented in various different forms. The embodiments provided below are provided to describe aspects and features of the present disclosure and allow one of ordinary skill in the art to which the present disclosure pertains to completely recognize the scope of the present disclosure. The present disclosure will be defined by the scope of the claims and their equivalents.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Each feature of the various embodiments of the present disclosure may be partially or entirely coupled or combined with each other, and is technically capable of various interlocking and driving, and each embodiment may be implemented independently of each other or may be implemented together in an association relationship.

Hereinafter, detailed embodiments will be described with reference to the accompanying drawings.

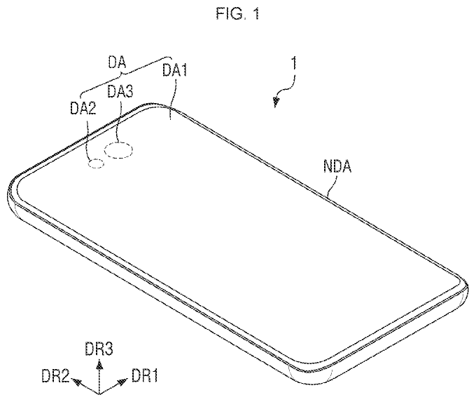

FIG. 1 is a schematic plan view of an electronic device according to an embodiment.

Referring to FIG. 1, an electronic device 1 is configured to display a moving image and/or a still image. The electronic device 1 may refer to any electronic device that provides (or includes) a display screen, such as a television, a laptop computer, a monitor, an advertising board, an Internet of Things (IoT) device, a mobile phone, a smart phone, a tablet personal computer (PC), an electronic watch, a smart watch, a watch phone, a head mounted display, a mobile communication terminal, an electronic diary, an electronic book, a portable multimedia player (PMP), a navigator, a game machine, a digital camera, a camcorder, and the like.

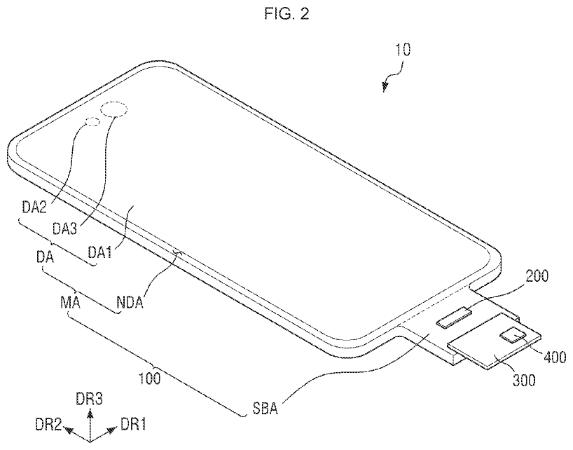

The electronic device 1 may include a display device (‘10’ in FIG. 2) having a display screen. Examples of the display device 10 include an inorganic light emitting diode display device, an organic light emitting display device, a quantum dot light emitting display device, a plasma display device, and a field emission display device. Hereinafter, the display device 10 is described as being an organic light emitting diode display device as an example, but the display device 10 is not limited to an organic light emitting diode display device. Another type of display device may be applied when the same technical spirit is applicable thereto.

Various modifications may be made to the shape of the electronic device 1. For example, the electronic device 1 may have a rectangular shape that is long in a horizontal direction, a rectangular shape that is long in a vertical direction, a square shape, a square shape with rounded corners (e.g., vertexes), other polygonal shapes, a circular shape, etc. A shape of a display area DA of the electronic device 1 may be similar to (or may correspond to) the overall shape of the electronic device 1. An electronic device 1 having a rectangular shape that is longer in a second direction DR2 is illustrated in FIG. 1.

The electronic device 1 may have the display area DA and a non-display area NDA. The display area DA is an area in which an image may be displayed, and the non-display area NDA is an area in which an image is not displayed. The display area DA may be referred to as an active area, and the non-display area NDA may be referred to as a non-active area. The display area DPA may generally occupy the center of the electronic device 1.

The display area DA may have (or may include) a first display area DA1, a second display area DA2, and a third display area DA3. The second display area DA2 and the third display area DA3 are areas in which components that provide (or add) various functions (or functionalities) to the electronic device 1 are disposed and may correspond to component areas.

FIG. 2 is a perspective view of the display device 10 included in the electronic device 1 shown in FIG. 1, according to an embodiment.

Referring to FIG. 2, the electronic device 1 according to an embodiment may include the display device 10. The display device 10 may provide an image displayed by the electronic device 1. The display device 10 may have a planar shape similar to that of the electronic device 1. For example, the display device 10 may have a shape similar to a rectangular shape having a short side in a first direction DR1 and a long side in a second direction DR2. A corner at where the short side in the first direction DR1 and the long side in the second direction DR2 meet may be rounded to have a curvature but is not limited thereto and may be formed at a right angle. The planar shape of the display device 10 is not limited to a quadrangle and may be similar to another polygonal shape, a circular shape, or an elliptical shape.

The display device 10 may include a display panel 100, a display driver 200, a circuit board 300 and a touch driver 400.

The display panel 100 may have a main area MA and a sub-area SBA.

The main area MA may include (or may form) the display area DA including pixels for displaying an image and the non-display area NDA disposed near the display area DA. The display area DA may have the first display area DA1, the second display area DA2, and the third display area DA3. The display area DA may emit light from a plurality of light emission areas or a plurality of opening areas (or open areas). For example, the display panel 100 may include a pixel circuit including switching elements, a pixel defining layer defining a light emission area or an opening area, and a self-light emitting element.

For example, the self-light emitting element may include at least one of an organic light emitting diode including an organic light emitting layer, a quantum dot light emitting diode (LED) including a quantum dot light emitting layer, an inorganic LED including an inorganic semiconductor, or a micro LED.

The non-display area NDA may be an outer area with respect to the display area DA. The non-display area NDA may be defined as an edge area of the main area MA of the display panel 100. The non-display area NDA may include a gate driver for supplying gate signals to gate lines and fan-out lines connecting the display driver 200 with the display area DA.

The sub-area SBA may be an area extended from one side of the main area MA. The sub-area SBA may include (or may be formed of) a flexible material capable of being bent, folded, rolled, or the like. For example, when the sub-area SBA is bent, the sub-area SBA may overlap the main area MA in a thickness direction (e.g., the third direction DR3). The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to a power line and may supply a gate control signal to the gate driver. The display driver 200 may be formed of an integrated circuit (IC) and then packaged on the display panel 100 by a Chip On Glass (COG) method, a Chip On Plastic (COP) method, or an ultrasonic bonding method. For example, the display driver 200 may be disposed in the sub-area SBA and may overlap the main area MA in the thickness direction by bending the sub-area SBA (e.g., due to the sub-area SBA being bent). In another example, the display driver 200 may be packaged on the circuit board 300.

The circuit board 300 may be attached onto the pad portion of the display panel 100 by an anisotropic conductive film (ACF). Lead lines of the circuit board 300 may be electrically connected to the pad portion of the display panel 100. The circuit board 300 may be a flexible film, such as a flexible printed circuit board, a printed circuit board, or a chip on film.

The touch driver 400 may be packaged on the circuit board 300. The touch driver 400 may be connected to a touch sensor of the display panel 100. The touch driver 400 may supply a touch driving signal to a plurality of touch electrodes of the touch sensor and may sense a change in capacitance between the plurality of touch electrodes. For example, the touch driving signal may be a pulse signal having a reference (or predetermined) frequency. The touch driver 400 may calculate (or may determine) whether or not input is performed and, if yes, input coordinates based on the change in capacitance between the plurality of touch electrodes. The touch driver 400 may be formed as an integrated circuit (IC).

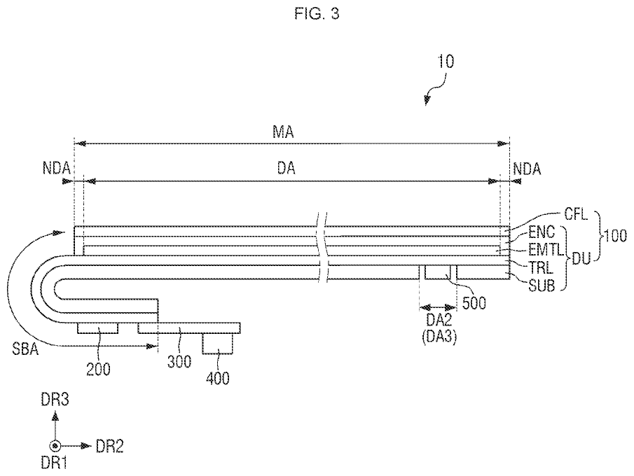

FIG. 3 is a cross-sectional view of the display device 10 shown in FIG. 2 taken from a side.

Referring to FIG. 3, the display panel 100 may include a display layer DU and a color filter layer CFL. The display layer DU may include a substrate SUB, a transistor layer TRL, a light emitting element layer EMTL, and an encapsulation layer ENC.

The substrate SUB may be a base substrate or a base member. The substrate SUB may be a flexible substrate capable of being bent, folded, rolled, or the like. For example, the substrate SUB may include a polymer resin, such as polyimide (PI), but is not limited thereto. In another embodiment, the substrate SUB may include a glass material or a metal material.

The transistor layer TRL may be disposed on the substrate SUB. The transistor layer TRL may include a plurality of transistors constituting a pixel circuit of the pixels. The transistor layer TRL may further include gate lines, data lines, power lines, gate control lines, fan-out lines for connecting the display driver 200 with the data lines, and lead lines for connecting the display driver 200 with the pad portion. Each of the transistors may include a semiconductor area, a source electrode, a drain electrode, and a gate electrode. For example, when the gate driver is formed on one side of the non-display area NDA of the display panel 100, the gate driver may include transistors.

The transistor layer TRL may be disposed in the display area DA, the non-display area NDA, and the sub-area SBA. The transistors, the gate lines, the data lines, and the power lines of respective pixels of the transistor layer TRL may be disposed in the display area DA. The gate control lines and the fan-out lines of the transistor layer TRL may be disposed in the non-display area NDA. The lead lines of the transistor layer TRL may be disposed in the sub-area SBA.

The light emitting element layer EMTL may be disposed on the transistor layer TRL. The light emitting element layer EMTL may include a plurality of light emitting elements, which include a first electrode, a second electrode, and a light emitting layer to emit light, and a pixel defining layer that defines the pixels. The plurality of light emitting elements of the light emitting element layer EMTL may be disposed in the display area DA.

In one embodiment, the light emitting layer may be an organic light emitting layer that includes an organic material. The light emitting layer may include a hole transporting layer, an organic light emitting layer, and an electron transporting layer. When the first electrode receives a voltage through the transistor of the transistor layer TRL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The encapsulation layer ENC may cover an upper surface and sides of the light emitting element layer EMTL and may protect the light emitting element layer EMTL. The encapsulation layer ENC may include at least one inorganic layer and at least one organic layer to encapsulate the light emitting element layer EMTL.

In another embodiment, a touch layer may be further disposed on the encapsulation layer ENC. The touch layer may include a plurality of touch electrodes for sensing a user's touch in a capacitance manner and touch lines for connecting the plurality of touch electrodes with the touch driver 400. For example, the touch layer may sense a user's touch in a mutual capacitance manner or a self-capacitance manner. In another embodiment, the touch layer may be disposed on a separate substrate disposed on the display layer DU. In such an embodiment, the substrate for supporting the touch layer may be a base member for encapsulating the display layer DU.

The color filter layer CFL may be disposed on the encapsulation layer ENC. The color filter layer CFL may include a plurality of color filters respectively corresponding to the plurality of light emission areas. Each of the color filters may selectively transmit light of a particular wavelength and may block or absorb light of another wavelength. The color filter layer CFL may absorb a portion of light introduced from the outside of the display device 10 to reduce reflective light due to external light. Therefore, the color filter layer CFL may prevent color distortion, which is caused by external light reflection.

Because the color filter layer CFL is directly disposed on the encapsulation layer ENC, the display device 10 may not require a separate substrate for the color filter layer CFL. Therefore, a thickness of the display device 10 may be relatively small.

In some embodiments, the display device 10 may further include an optical device 500. The optical device 500 may be disposed in the second display area DA2 or the third display area DA3. The optical device 500 may emit or receive light of an infrared, ultraviolet, or visible band. For example, the optical device 500 may be an optical sensor for sensing light incident on the display device 10, such as a proximity sensor, an illuminance sensor, and a camera sensor or an image sensor.

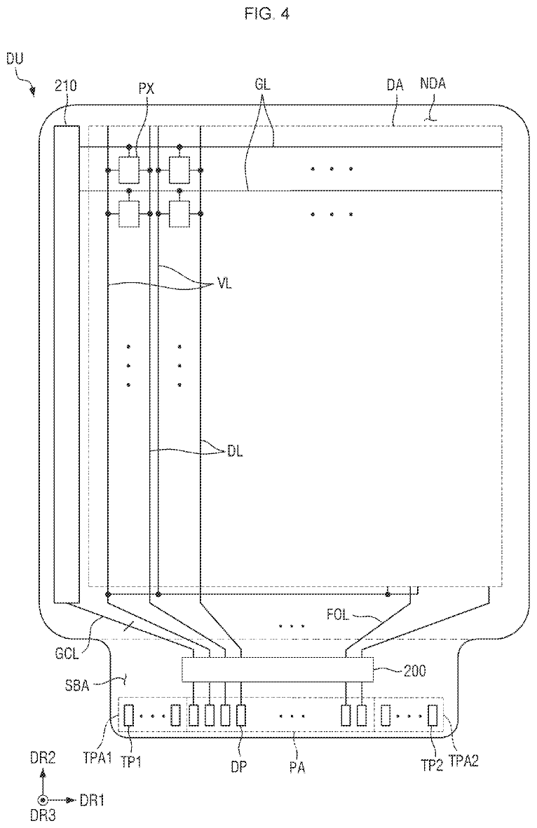

FIG. 4 is a plan view of a display layer of the display device 10 according to an embodiment.

Referring to FIG. 4, the display layer DU may have (or may form) the display area DA and the non-display area NDA.

The display area DA may be disposed at the center of the display panel 100. A plurality of pixels PX, a plurality of gate lines GL, a plurality of data lines DL, and a plurality of power lines VL may be disposed in the display area DA. Each of the plurality of pixels PX may be defined as a minimum unit for emitting light.

The plurality of gate lines GL may supply the gate signals received from a gate driver 210 to the plurality of pixels PX. The plurality of gate lines GL may extend in the first direction DR1 and may be spaced apart from each other in the second direction DR2 crossing the first direction DR1.

The plurality of data lines DL may supply the data voltages received from the display driver 200 to the plurality of pixels PX. The plurality of data lines DL may extend in the second direction DR2 and may be spaced apart from each other in the first direction DR1.

The plurality of power lines VL may supply the power voltage received from the display driver 200 to the plurality of pixels PX. The power voltage may be at least one of a driving voltage, an initialization voltage, a reference voltage, or a low potential voltage. The plurality of power lines VL may extend in the second direction DR2 and may be spaced apart from each other in the first direction DR1.

The non-display area NDA may surround (or may extend around a periphery of) the display area DA. The gate driver 210, fan-out lines FOL, and gate control lines GCL may be disposed in the non-display area NDA. The gate driver 210 may generate a plurality of gate signals based on the gate control signal and may sequentially supply the plurality of gate signals to the plurality of gate lines GL in accordance with a set order.

The fan-out lines FOL may extend from the display driver 200 to the display area DA. The fan-out lines FOL may supply the data voltages received from the display driver 200 to the plurality of data lines DL.

The gate control line GCL may extend from the display driver 200 to the gate driver 210. The gate control line GCL may supply the gate control signal received from the display driver 200 to the gate driver 210.

The sub-area SBA may include the display driver 200, the pad area PA, and first and second touch pad areas TPA1 and TPA2.

The display driver 200 may output signals and voltages for driving the display panel 100 to the fan-out lines FOL. The display driver 200 may supply the data voltages to the data lines DL through the fan-out lines FOL. The data voltages may be supplied to the plurality of pixels PX and may control luminance of the plurality of pixels PX. The display driver 200 may supply the gate control signal to the gate driver 210 through the gate control line GCL.

The pad area PA, the first touch pad area TPA1, and the second touch pad area TPA2 may be disposed at an edge of the sub-area SBA. The pad area PA, the first touch pad area TPA1, and the second touch pad area TPA2 may be electrically connected to the circuit board 300 by using a material, such as an anisotropic conductive film or a self-assembly anisotropic conductive paste (SAP).

The pad area PA may include a plurality of display pad portions DP. The plurality of display pad portions DP may be connected to a graphic (or video) system through the circuit board 300. The plurality of display pad portion DP may be connected to the circuit board 300 to receive digital video data and may supply the digital video data to the display driver 200.

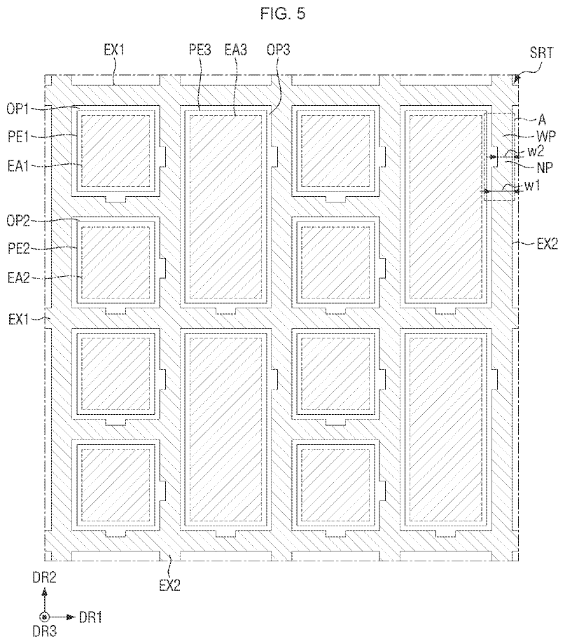

FIG. 5 is a plan view of a pixel electrode and a separator SRT of the display device 10 according to an embodiment.

As shown in FIG. 5, the display device 10 may include a first pixel electrode PE1, a second pixel electrode PE2, a third pixel electrode PE3, and a separator SRT.

The first pixel electrode PE1, the second pixel electrode PE2, and the third pixel electrode PE3 may be surrounded by (e.g., may be surrounded along their peripheries by) the separator SRT. For example, in a plan (or plane) view, the first pixel electrode PE1, the second pixel electrode PE2, and the third pixel electrode PE3 may be surrounded by the separator SRT. In other words, the first pixel electrode PE1, the second pixel electrode PE2, and the third pixel electrode PE3 may be respectively disposed in areas (hereinafter, opening areas or open areas) defined by the separator SRT. For example, the first pixel electrode PE1 may be disposed in a first opening area OP1 defined by the separator SRT, the second pixel electrode PE2 may be disposed in a second opening area OP2 defined by the separator SRT, and the third pixel electrode PE3 may be disposed in a third opening area OP3 defined by the separator SRT.

The separator SRT may include a plurality of first extension portions EX1 extending in the first direction DR1 and a plurality of second extension portions EX2 extending in the second direction DR2. The first extension portions EX1 may cross the second extension portions EX2. The first extension portion EX1 and the second extension portion EX2 may be connected to each other at a crossing point between the first extension portion EX1 and the second extension portion EX2. The first extension portion EX1 and the second extension portion EX2 may be integrally formed. The first pixel electrode PE1, the second pixel electrode PE2, and the third pixel electrode PE3 may be disposed in the opening areas OP1, OP2, and OP3 defined by being surrounded by the plurality of first extension portions EX1 and the plurality of second extension portions EX2.

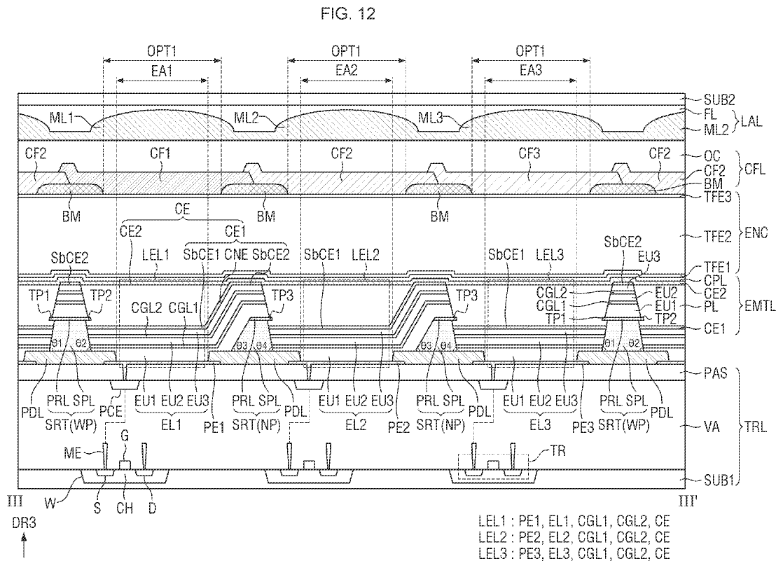

A portion of the first pixel electrode PE1 e.g., an edge of the first pixel electrode PE2), a portion of the second pixel electrode PE2 (e.g., an edge of the second pixel electrode PE2), and a portion of the third pixel electrode PE3 (e.g., an edge of the third pixel electrode PE3) may be covered by a bank (‘PDL’ in FIG. 12), to be described below. In other words, a portion of the first pixel electrode PE1 (e.g., an edge of the first pixel electrode PE1), a portion of the second pixel electrode PE2 (e.g., an edge of the second pixel electrode PE2), and a portion of the third pixel electrode PE3 (e.g., an edge of the third pixel electrode PE3) may partially overlap the bank PDL. Areas exposed without being covered by the bank PDL from among the first pixel electrode PE1, the second pixel electrode PE2, and the third pixel electrode PE3 may be defined as a first light emission area EA1, a second light emission area EA2, and a third light emission area EA3, respectively.

At least a portion of the separator SRT may have a different width from another portion thereof. For example, an upper surface of at least a portion of the separator SRT may have a smaller width than an upper surface of another portion thereof. In such an embodiment, when a portion of the separator SRT that has an upper surface with a relatively large width is defined as a wide width portion WP and a portion of the separator that has an upper surface with a relatively small width is defined as a narrow width portion NP, a width w2 of the narrow width portion NP may be smaller than a width w1 of the wide width portion WP. The width w1 or w2 may be, for example, a size in the first direction DR1 or in the second direction DR2. For example, when the narrow width portion NP is disposed in the first extension portion EX1 of the separator SRT, each of the width w1 of the wide width portion WP of the first extension portion EX1 and the width w2 of the narrow width portion NP may mean a size (or a distance) in the second direction DR2. When the narrow width portion NP is disposed in the second extension portion EX2 of the separator SRT, each of the width w1 of the wide width portion WP of the second extension portion EX2 and the width w2 of the narrow width portion NP may mean a size (or a distance) in the first direction DR1.

In the separator SRT, the side of the narrow width portion NP may have a gradient of a different size from the side of the wide width portion WP. For example, the gradient of the side of the narrow width portion NP may be smaller than that of the side of the wide width portion WP. In such an embodiment, the gradient of the side of the narrow width portion NP and the gradient of the side of the wide width portion WP may mean, for example, a slope with respect to a lower surface of the separator SRT. The lower surface of the separator SRT may be a surface facing the upper surface of the separator SRT or a surface opposite to the upper surface of the separator SRT. In one embodiment, the lower surface of the separator SRT may be, for example, a surface that is in contact with the bank PDL. In other words, the lower surface of the separator SRT may be included in the interface between the separator SRT and the bank PDL.

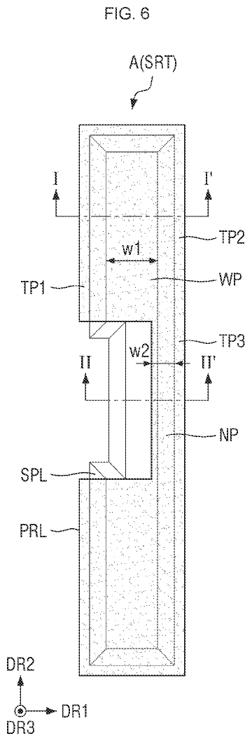

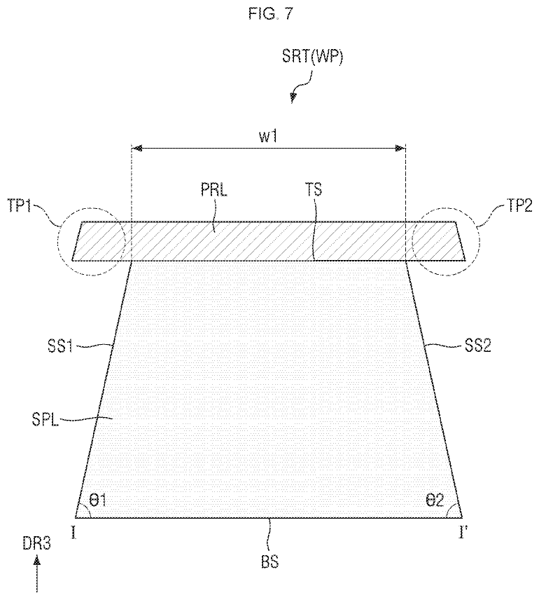

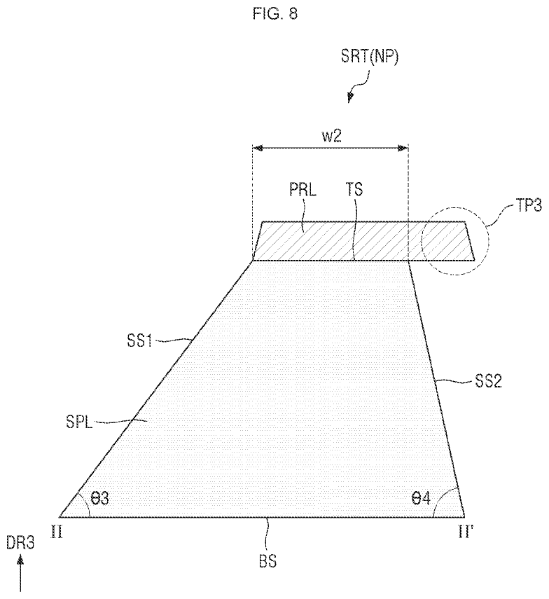

FIG. 6 is an enlarged perspective view of the portion A in FIG. 5, FIG. 7 is a cross-sectional view taken along the line I-I′ of FIG. 6, and FIG. 8 is a cross-sectional view taken along the line II-II′ of FIG. 6.

As shown in FIGS. 6, 7, and 8, the separator SRT may include a support layer SPL and a protrusion layer PRL. The support layer SPL may be disposed on the bank PDL, and the protrusion layer PRL may be disposed on the support layer SPL.

At least one side of the protrusion layer PRL may be more protruded (or extended) in at least one of the first direction DR1 or the second direction DR2 than the support layer SPL so that at least one side of the protrusion layer PRL is not supported by (e.g., extends beyond) the support layer SPL. In other words, at least one side of the protrusion layer PRL may be more protruded in the first direction DR1 and the second direction DR2 than the support layer SPL so that at least one side of the protrusion layer PRL does not overlap the interface between the protrusion layer PRL and the support layer SPL, thereby forming a tip TP1, TP2, and/or TP3. The support layer SPL may support the protrusion layer PRL in the third direction DR3, and thus, the protrusion layer PRL may include the tip TP1, TP2, and/or TP3 that is more extended than (e.g., that extends beyond) the support layer SPL in a direction crossing the third direction DR3 on the support layer SPL (e.g., at least one of the first direction DR1 or the second direction DR2). The tip TP1, TP2, or TP3 is not supported by the support layer SPL. Therefore, a virtual extension line extended along a side of the support layer SPL may cross the protrusion layer PRL. For example, an area (e.g., a surface area) of the protrusion layer PRL may be larger than that of an upper surface of the support layer SPL. The area of the protrusion layer PRL may be, for example, an area defined by a size of the protrusion layer PRL in the first direction DR1 and a size of the protrusion layer in the second direction DR2, and the area of the upper surface of the support layer SPL may be an area defined by a size of the upper surface in the first direction DR1 and a size of the upper surface in the second direction DR2. Therefore, at least one tip TP1, TP2, or TP3 of the protrusion layer PRL may not be in contact with the support layer SPL. An undercut may occur below the tip TP1, TP2, or TP3 due to the tip TP1, TP2, or TP3 of the protrusion layer PRL when the separator SRT is formed. Therefore, at least one side of the separator SRT may have an overhang structure.

For example, as shown in FIGS. 6 and 7, the wide width portion WP of the separator SRT may include the protrusion layer PRL having the first tip TP1 and the second tip TP2, which are more protruded toward both sides than the support layer SPL. In other words, both end portions of the protrusion layer PRL on the wide width portion WP may include the first tip TP1 and the second tip TP2, which are not supported by the support layer SPL (e.g., are not in contact with the support layer SPL).

The support layer SPL of the wide width portion WP may have a trapezoidal cross-section. An upper surface TS of the support layer SPL of the wide width portion WP may be in contact with the protrusion layer PRL.

A first side SS1 of the wide width portion WP may connect (or may extend between) one end portion of the upper surface TS of the wide width portion WP with one end portion of a lower surface BS of the wide width portion WP.

A second side SS2 of the wide width portion WP may connect the other end of the upper surface TS of the wide width portion WP with the other end of the lower surface BS of the wide width portion WP.

The first side SS1 and the second side SS2 of the wide width portion WP may face each other. The upper surface TS and the lower surface BS of the wide width portion WP may face each other.

A first angle θ1 formed between the lower surface BS of the support layer SPL and the first side SS1 of the support layer SPL in the wide width portion WP may be the same as a second angle θ2 formed between the lower surface BS of the support layer SPL and the second side SS2 of the support layer SPL. In other embodiments, however, the first angle θ1 and the second angle θ2 may be different from each other.

Both the first angle θ1 and the second angle θ2 may be acute angles.

As shown in FIGS. 6 and 8, the narrow width portion NP of the separator SRT may include the protrusion layer PRL having one third tip TP3 more protruded toward both sides than the support layer SPL. In other words, one end portion of the protrusion layer PRL on the narrow width portion NP may include one third tip TP3 that is not supported by the support layer SPL (e.g., is not in contact with the support layer SPL). The third tip TP3 of the narrow width portion NP may be disposed to be adjacent to the second side SS2 of the support layer SPL. In other words, the third tip TP3 of the narrow width portion NP may be disposed to be closer to the second side SS2 from among the first and second sides SS1 and SS2.

The support layer SPL of the narrow width portion NP may have a trapezoidal cross-section. The upper surface TS of the support layer SPL of the narrow width portion NP may be in contact with the protrusion layer PRL.

The first side SS1 of the narrow width portion NP may connect one end portion of the upper surface TS of the narrow width portion NP with one end portion of the lower surface BS of the narrow width portion NP.

The second side SS2 of the narrow width portion NP may connect the other end portion of the upper surface TS of the narrow width portion NP with the other end portion of the lower surface BS of the narrow width portion NP.

The first side SS1 and the second side SS2 of the narrow width portion NP may face each other. The upper surface TS and the lower surface BS of the narrow width portion NP may face each other.

A third angle θ3 formed between the lower surface of the support layer SPL and the first side SS1 of the support layer SPL in the narrow width portion NP may be different from a fourth angle θ4 formed between the lower surface BS of the support layer SPL and the second side SS2 of the support layer SPL. For example, the third angle θ3 may be smaller than the fourth angle θ4. For example, the first side SS1 of the narrow width portion NP is farther from the third tip TP3 than the second side SS2 of the narrow width portion NP is, and thus, the third angle θ3 between the first side SS1 and the support layer SPL may be smaller than the fourth angle θ4 between the second side SS2 and the support layer SPL. In other words, the third angle θ3 formed between the first side SS1, which is disposed to be relatively farther from the third tip TP3, and the lower surface BS may be smaller than the fourth angle θ4.

The third angle θ3 and the fourth angle θ4 may be acute angles.

Also, the third angle θ3 of the narrow width portion NP may be smaller than the first angle θ1 of the wide width portion WP. In addition, the third angle θ3 of the narrow width portion NP may be smaller than the second angle θ2 of the wide width portion WP.

The fourth angle θ4 of the narrow width portion NP may be the same as the first angle θ1 of the wide width portion WP. In addition, the fourth angle θ4 of the narrow width portion NP may be the same as the second angle θ2 of the wide width portion WP.

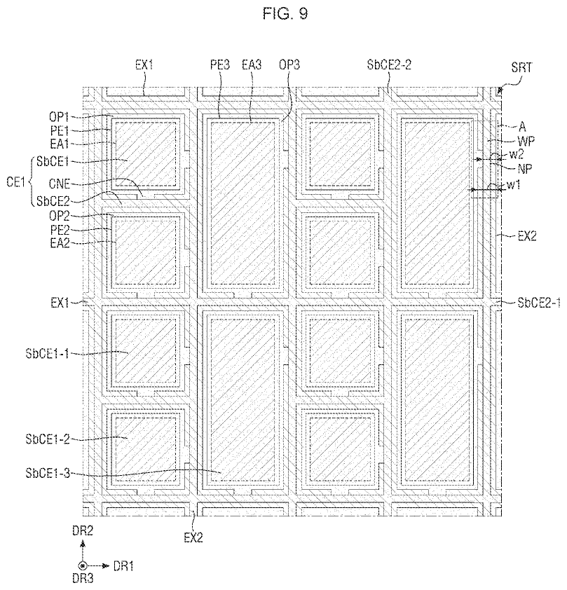

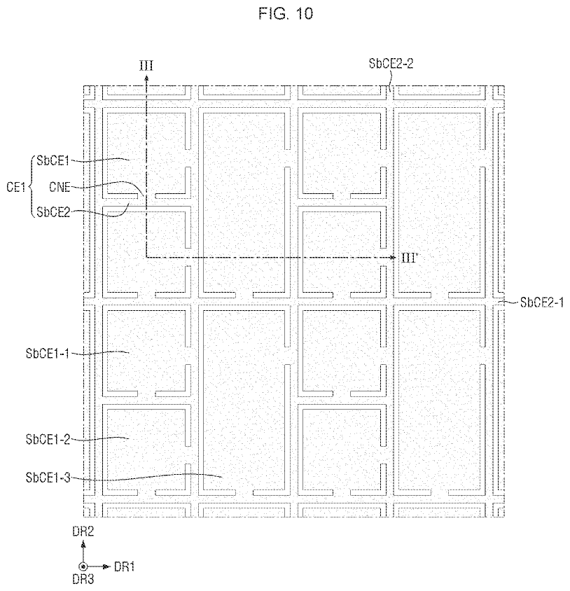

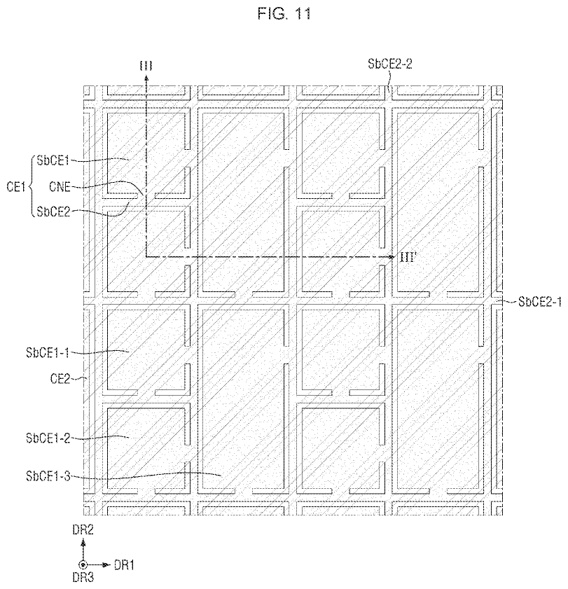

FIG. 9 is a plan view of a pixel electrode, a separator SRT, and a first common electrode CE1 of the display device 10 according to another embodiment, FIG. 10 is a plan view of the first common electrode CE1 shown in FIG. 9, and FIG. 11 is a plan view of a first common electrode CE1 and a second common electrode CE2 of the display device 10 according to another embodiment.

The first to third pixel electrodes PE1, PE2, and PE3, the first to third light emission areas EA1, EA2, and EA3, and the separator SRT shown in FIG. 9 are the same as the first to third pixel electrodes PE1, PE2, and PE3, the first to third light emission areas EA1, EA2, and EA3, and the separator SRT shown in FIG. 5, and thus, the description of the first to third pixel electrodes PE1, PE2, and PE3, the first to third light emission areas EA1, EA2, and EA3, and the separator SRT shown in FIG. 9 will be understood with reference to the description of FIG. 5.

As shown in FIGS. 10 and 11, a common electrode CE (e.g., a cathode electrode of a light emitting element) may include a first common electrode CE1 and a second common electrode CE2. The first common electrode CE1 and the second common electrode CE2 may be disposed on respective layers different from each other. For example, the second common electrode CE2 may be disposed on the first common electrode CE1 in the third direction DR3. The first common electrode CE1 may be disposed on the first to third pixel electrodes PE1, PE2, and PE3 and the separator SRT in the third direction DR3.

As shown in FIGS. 9 and 10, the first common electrode CE1 may include a first sub-common electrode SbCE1, a second sub-common electrode SbCE2, and a connection electrode CNE. The first sub-common electrode SbCE1 and the second sub-common electrode SbCE2 may be connected to each other through the connection electrode CNE. The first sub-common electrode SbCE1, the second sub-common electrode SbCE2, and the connection electrode CNE may be integrally formed. The first sub-common electrode SbCE1 and the second sub-common electrode SbCE2 may be disposed on respective layers different from each other. For example, the second sub-common electrode SbCE2 may be disposed to be higher than (e.g., to be on a layer above that of) the first sub-common electrode SbCE1 in the third direction DR3.

As shown in FIG. 9, the first sub-common electrode SbCE1 may be disposed to overlap each of the pixel electrodes PE1, PE2, and PE3. For example, the first sub-common electrode SbCE1 may include a (1-1)th sub-common electrode SbCE1-1, a (1-2)th sub-common electrode SbCE1-2, and a (1-3)th sub-common electrode SbCE1-3. The (1-1)th sub-common electrode SbCE1-1 overlaps the first pixel electrode PE1, the (1-2)th sub-common electrode SbCE1-2 overlaps the second pixel electrode PE2, and the (1-3)th sub-common electrode SbCE1-3 overlaps the third pixel electrode PE3.

As shown in FIG. 9, the second sub-common electrode SbCE2 may overlap the separator SRT. For example, the second sub-common electrode SbCE2 may include a (2-1)th sub-common electrode SbCE2-1 extending in the first direction DR1 and a (2-2)th sub-common electrode SbCE2-2 extend in the second direction DR2. The (2-1)th sub-common electrode SbCE2-1 may overlap the first extension portion EX1 of the separator SRT, and the (2-2)th sub-common electrode SbCE2-2 may overlap the second extension portion EX2 of the separator SRT.

The connection electrode CNE may connect the first sub-common electrode SbCE1 with the second sub-common electrode SbCE2. The connection electrode CNE may be disposed to correspond to the narrow width portion NP of the separator SRT. For example, the connection electrode CNE may be disposed in a groove defined by the narrow width portion NP and the wide width portion WP.

As shown in FIG. 11, the second common electrode CE2 may be disposed on the first common electrode CE1 in the third direction DR3. The second common electrode CE2 may overlap the first common electrode CE1. For example, the second common electrode CE2 may be disposed on the first common electrode CE1 to cover the entire surface of the first common electrode CE1. The first common electrode CE1 and the second common electrode CE2 may be connected to each other on the separator SRT.

Because the first common electrode CE1 shown in FIG. 11 is the same as the first common electrode CE1 shown in FIG. 10, the description of the first common electrode CE1 shown in FIG. 11 will be understood with reference to the description of FIG. 10.

FIG. 12 is a cross-sectional view taken along the line III-III′ of FIGS. 10 and 11.

As shown in FIG. 12, the display device 10 may include a transistor layer TRL, a light emitting element layer EMTL, an encapsulation layer ENC, a color filter layer CFL, a lens array layer LAL, and an encapsulation substrate SUB2.

A base substrate SUB1 may be a silicon substrate, a germanium substrate, or a silicon-germanium substrate. The base substrate SUB1 may be a substrate doped with first type impurities.

A well area W may be disposed on the base substrate SUB1 (or inside the base substrate SUB1). The well area W may be an area doped with second type impurities. The second type impurities may be different from the first type impurities. For example, when the first type impurities are p-type impurities, the second type impurities may be n-type impurities. When the first type impurities are n-type impurities, the second type impurity may be p-type impurities.

A source area S, a drain area D, and a channel area CH of the transistor TR may be disposed in the well area W. For example, the source area S (or source electrode) and the drain area D (or drain electrode) of the transistor TR may be disposed in the well area W. Each of the source area S and the drain area D may be an area doped with the first type impurities. A gate electrode G of the transistor TR may cross and overlap the well area W. In a plan view, the well area W crossing the gate electrode G may be defined as two areas, the source area S may be disposed in any one of the two areas and the drain area D may be disposed in the other one of the two areas. In other words, in the well area W, the source area S and the drain area D may be disposed at both sides of the gate electrode G with the gate electrode G interposed therebetween. The channel area CH of the transistor may be disposed in an area of the well area that overlaps the gate electrode G.

The source area S may include a first lightly doped area having a relatively lower impurity concentration than other portions of the source area S. In other words, a portion of the source area S may include an impurity concentration lower than that of the other portions of the source area S. The drain area D may include a second lightly doped area having a relatively lower impurity concentration than other portions of the drain area D. In other words, a portion of the drain area D may having an impurity concentration lower than that of the other portions of the drain area D.

The first lightly doped area and the second lightly doped area may be disposed to be adjacent to the channel area CH of the transistor TR. For example, the first lightly doped area may be disposed to be adjacent to the channel area CH, thereby overlapping a first spacer disposed on one side of the gate electrode G, and the second lightly doped area may be disposed to be adjacent to the channel area CH, thereby overlapping a second spacer disposed on the other side of the gate electrode G. A distance between the heavily doped area of the source area S and the heavily doped area of the drain area D may be increased by the first lightly doped area and the second lightly doped area, and as the distance increases, a length of the channel area CH may be increased. Therefore, punch-through and hot carrier phenomena due to a short channel may be avoided.

An interlayer insulating layer VA may be disposed on the base substrate SUB1.

A passivation layer PAS may be disposed on the interlayer insulating layer VA.

A light emitting element layer EMTL may be disposed on the passivation layer PAS. The light emitting element layer EMTL may include, for example, a first light emitting element LEL1, a second light emitting element LEL2, and a third light emitting element LEL3. Each of the first light emitting element LEL1, the second light emitting element LEL2, and the third light emitting element LEL3 may provide (or may emit) white light.

The first light emitting element LEL1 may include a first pixel electrode PE1 (e.g., a first anode electrode), a first light emitting layer EL1, a first charge generation layer CGL1, a second charge generation layer CGL2, a common electrode CE (e.g., a cathode electrode), and a planarization layer PL.

The second light emitting element LEL2 may include a second pixel electrode PE2 (e.g., a second anode electrode), a second light emitting layer EL2, a first charge generation layer CGL1, a second charge generation layer CGL2, a common electrode CE (e.g., a cathode electrode), and a planarization layer PL.

The third light emitting element LEL3 may include a third pixel electrode PE3 (e.g., a third anode electrode), a third light emitting layer EL3, a first charge generation layer CGL1, a second charge generation layer CGL2, a common electrode CE (e.g., a cathode electrode), and a planarization layer PL.

The first pixel electrode PE1, the second pixel electrode PE2, and the third pixel electrode PE3 may be connected to each source area S of respective transistors TR through a pixel connection electrode PCE and a metal connection layer ME.

The pixel electrode may include a first pixel electrode PE1 of a first pixel, a second pixel electrode PE2 of a second pixel, and a third pixel electrode PE3 of a third pixel. The first pixel electrode PE1 may be disposed to correspond to the first light emission area EA1, the second pixel electrode PE2 may be disposed to correspond to the second light emission area EA2, and the third pixel electrode PE3 may be disposed to correspond to the third light emission area EA3.

The bank PDL (or pixel defining layer) may be disposed on the first pixel electrode PE1, the second pixel electrode PE2, and the third pixel electrode PE3.

The separator SRT may be disposed on the bank PDL. The separator SRT may include a support layer SPL and a protrusion layer PRL on the support layer SPL. A side shape of the separator SRT may be a structure formed by an etch rate difference in an etching process because the support layer SPL and the protrusion layer PRL include respective materials that are different from each other. According to an embodiment, the protrusion layer PRL may include a material having an etch rate lower than that of the support layer SPL such that the support layer SPL may be further etched in the process of forming opening areas OP1, OP2, and OP3 of the separator SRT to form an undercut below the tips TP1, TP2, and TP3 of the protrusion layer PRL. In one embodiment, the support layer SPL may include silicon nitride (SiNₓ), and the protrusion layer PRL may include silicon oxide (SiOₓ).

The bank PDL may define light emission areas (e.g., a first light emission area EA1 of the first pixel, a second light emission area EA2 of the second pixel, and a third light emission area EA3 of the third pixel) of the pixel electrodes PE1, PE2, and PE3. To this end, the bank PDL may be disposed (or arranged) to expose a partial area of each of the first pixel electrode PE1, the second pixel electrode PE2, and the third pixel electrode PE3 on the passivation layer PAS. The bank PDL may cover edges of each of the first pixel electrode PE1, the second pixel electrode PE2, and the third pixel electrode PE3. The bank PDL may be formed of an organic material, such as an acryl resin, an epoxy resin, a phenolic resin, a polyimide resin, or a polyimide resin.

A light emitting layer may be disposed on each of the pixel electrodes PE1, PE2, and PE3. For example, a first light emitting layer EL1 may be disposed on the first light emission area EA1 of the first pixel electrode PE1, a second light emitting layer EL2 may be disposed on the second light emission area EA2 of the second pixel electrode PE2, and a third light emitting layer EL3 may be disposed on the third light emission area EA3 of the third pixel electrode PE3.

Each of the light emitting layers EL1, EL2, and EL3 may include a plurality of light emitting units. For example, the first light emitting layer EL1 may include a first light emitting unit EU1, a second light emitting unit EU2, and a third light emitting unit EU3, which are stacked in the third direction DR3, and the second light emitting layer EL2 may include a first light emitting unit EU1, a second light emitting unit EU2, and a third light emitting unit EU3, which are stacked in the third direction. The third light emitting layer EL3 may include a first light emitting unit EU1, a second light emitting unit EU2, and a third light emitting unit EU3, which are stacked in the third direction DR. For example, each light emitting layer may have a tandem structure.

The light emitting units EU1, EU2, and EU3 may provide light of different wavelengths. For example, the first light emitting unit EU1, the second light emitting unit EU2, and the third light emitting unit EU3 may emit light of different colors.

The first light emitting unit EU1 may be disposed on each of the pixel electrodes PE1, PE2, and PE3. The first light emitting unit EU1 may include a hole transporting layer, an organic material layer, and an electron transporting layer. The organic material layer may include a host and a dopant. The organic material layer may include a material for emitting light (e.g., for emitting a color light) and may be formed by using a phosphorescent material or a fluorescent material. The aforementioned first light emitting unit EU1 may provide light of a first color (e.g., blue). To this end, the organic material layer of the first light emitting unit EU1 may include a host material containing carbazole biphenyl (CBP) or mCP (3,3′-Di(9H-carbazol-9-yl)-1,1′-biphenyl) and may be a phosphorescent material that includes a dopant material containing (4,6-F2ppy)2Irpic or L2BD111 but is not limited thereto.

The second light emitting unit EU2 may be disposed on the first light emitting unit EU1 of each of the pixel electrodes PE1, PE2, and PE3. The second light emitting unit EU2 may include a hole transporting layer, an organic material layer, and an electron transporting layer. The organic material layer may include a host and a dopant. The organic material layer may include a material for emitting a color light and may be formed by using a phosphorescent material or a fluorescent material. The aforementioned second light emitting unit EU2 may provide light of a second color (e.g., red). To this end, the organic material layer of the second light emitting unit EU2 includes a host material containing carbazole biphenyl (CBP) or mCP (1,3-bis(carbazol-9-yl) and may be a phosphorescent material that includes a dopant containing any one or more selected from PIQIr (acac) (bis(1-phenylisoquinoline) acetylacetonate iridium), PQIr (acac) (bis(1-phenylquinoline) acetylacetonate iridium), PQIr (tris(1-phenylquinoline) iridium), and PtOEP (octaethylporphyrin platinum). In another embodiment, the organic material layer of the second light emitting unit EU2 may be a fluorescent material containing PBD:Eu(DBM)3(Phen) or Perylene but is not limited thereto.

The third light emitting unit EU3 may be disposed on the second light emitting unit EU2 of each of the pixel electrodes PE1, PE2, and PE3. The third light emitting unit EU3 may include a hole transporting layer, an organic material layer, and an electron transporting layer. The organic material layer may include a host and a dopant. The organic material layer may include a material for emitting a color light and may be formed by using a phosphorescent material or a fluorescent material. The aforementioned third light emitting unit EU3 may provide light of a third color (e.g., green). To this end, the organic material layer of the third light emitting unit EU3 may include a host material containing CBP or mCP and may be a phosphorescent material that includes a dopant material containing Ir(ppy)3(fac tris(2-phenylpyridine) iridium). In another embodiment, the organic material layer of the third light emitting unit EU3 for emitting light of a third color may be a fluorescent material containing Alq3(tris(8-hydroxyquinolino)aluminum) but is not limited thereto.

Each of the light emitting layers EL1, EL2, and EL3 may provide white light by mixing light of a first color (e.g., blue) from the first light emitting unit EU1, light of a second color (e.g., red) from the second light emitting unit EU2, and light of a third color (e.g., green) from the third light emitting unit EU3. For example, each of the first light emitting layer EL1, the second light emitting layer EL2, and the third light emitting layer EL3 may provide white light.

The charge generation layer may be disposed between the light emitting units adjacent to each other in the third direction DR3. For example, the charge generation layer may include a first charge generation layer CGL1 and a second charge generation layer CGL2. The first charge generation layer CGL1 may be disposed between the first light emitting unit EU1 and the second light emitting unit EU2, and the second charge generation layer CGL2 may be disposed between the second light emitting unit EU2 and the third light emitting unit EU3.

Each charge generation layer may include a negative charge generation layer and a positive charge generation layer. For example, the first charge generation layer CGL1 may include a first negative charge generation layer nCGL1 and a first positive charge generation layer pCGL1, which are stacked in the third direction DR3, and the second charge generation layer CGL2 may include a second negative charge generation layer nCGL2 and a second positive charge generation layer pCGL2, which are stacked in the third direction DR3. The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In addition, each of the light emitting layers EL1, EL2, and EL3, the first charge generation layer CGL1, and the second charge generation layer CGL2 may be disposed on the separator SRT. For example, the first light emitting unit EU1, the first charge generation layer CGL1, the second light emitting unit EU2, the second charge generation layer CGL2, and the third light emitting unit EU3 may be disposed on the protrusion layer PRL of the separator SRT.

In addition, each of the light emitting layers EL1, EL2 and EL3, the first charge generation layer CGL1, and the second charge generation layer CGL2 may be disposed on the bank PDL. For example, the first light emitting unit EU1, the first charge generation layer CGL1, the second light emitting unit EU2, the second charge generation layer CGL2, and the third light emitting unit EU3 may be disposed on the bank PDL.

The first sub-common electrode SbCE1 may be disposed on the light emitting layer. For example, the first sub-common electrode SbCE1 may be disposed on the first light emitting layer EL1 on the first pixel electrode PE1, the second light emitting layer EL2 on the second pixel electrode PE2, the third light emitting layer EL3 on the third pixel electrode PE3, the light emitting layer on the separator SRT and the light emitting layer on the bank PDL. For example, the first sub-common electrode SbCE1 may be disposed on the first light emitting layer EL1 (e.g., the third light emitting unit EU3) on the first pixel electrode PE1, the second light emitting layer EL2 (e.g., the third light emitting unit EU3) on the second pixel electrode PE2, the third light emitting layer EL3 (e.g., the third light emitting unit UE3) on the third pixel electrode PE3, and the light emitting layer (e.g., the third light emitting unit EU3) on the bank PDL, and the second sub-common electrode SbCE2 may be disposed on the light emitting layer (e.g., the third light emitting unit EU3) on the separator SRT. Also, the connection electrode CNE may be further disposed in the narrow width portion NP of the separator SRT.

The planarization layer PL may be disposed on the first sub-common electrode SbCE1 and the connection electrode CNE. For example, the planarization layer PL may be disposed between the first sub-common electrode SbCE1 and the second common electrode CE2, which will be described below, and the planarization layer PL may be disposed between the connection electrode CNE and the second common electrode CE2. The planarization layer PL may not be disposed on the second sub-common electrode SbCE2. In other words, the second sub-common electrode SbCE2 may be exposed above the planarization layer PL. In addition, the planarization layer PL may be further disposed between the tips (e.g., the first tip TP1, the second tip TP2, and the third tip TP3) of the protrusion layer of the separator SRT and the first sub-common electrode SbCE1. The planarization layer PL may be made of, for example, an organic layer. As another example, the planarization layer PL may be made of an inorganic layer.

The second common electrode CE2 may be disposed on the planarization layer PL and the second sub-common electrode SbCE2. For example, the second common electrode CE2 may be disposed on the entire surface of the base substrate SUB1 including the planarization layer PL and the second sub-common electrode SbCE2. The second common electrode CE2 may be electrically connected to the second sub-common electrode SbCE2. For example, the second common electrode CE2 may be in contact (e.g., in direct contact) with the second sub-common electrode SbCE2 disposed on the separator SRT. Therefore, the second common electrode CE2 may be electrically connected to the first sub-common electrode SbCE1 and the second sub-common electrode SbCE2 of the first common electrode CE1. The first common electrode CE1 including the first sub-common electrode SbCE1 and the second sub-common electrode SbCE2 may be made of an alloy of, for example, silver (Ag) and magnesium (Mg). For example, the first common electrode CE1 may be made of AgMg. Also, the second common electrode CE2 may be made of, for example, Indium Tin Oxide (ITO).

A capping layer CPL may be disposed on the second common electrode CE2. The capping layer CPL may include an inorganic insulating material to cover patterns disposed on the separator SRT and the light emitting elements. The capping layer CPL may prevent the light emitting elements from being damaged by external air and may prevent the patterns disposed on the separator SRT from being peeled off during the fabricating process of the display device 10. In an embodiment, the capping layer CPL may include aluminum oxide, titanium oxide, tantalum oxide, hafnium oxide, zinc oxide, silicon oxide, silicon nitride, and/or silicon oxynitride.

An encapsulation layer ENC may be disposed on the capping layer CPL. The encapsulation layer ENC may cover an upper surface and a side of the light emitting element layer EMTL and may protect the light emitting element layer EMTL. The encapsulation layer ENC may include at least one inorganic layer and at least one organic layer to encapsulate the light emitting element layer EMTL. The encapsulation layer ENC may include at least one inorganic layer TFE1, TFE3 to prevent oxygen or moisture from permeating into the light emitting element layer EMTL. The encapsulation layer ENC may include at least one organic layer TFE2 to protect the light emitting element layer EMTL from particles, such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be disposed on the capping layer CPL, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may each be a multi-layer in which one or more inorganic layers of a silicon nitride layer, a silicon oxynitride layer, a silicon oxide layer, a titanium oxide layer, and/or an aluminum oxide layer are alternately stacked. The encapsulation organic layer TFE2 may be an organic layer, such as an acryl resin, an epoxy resin, a phenolic resin, a polyamide resin, or a polyimide resin.

A light shielding layer BM may be disposed on the encapsulation layer ENC. The light shielding layer BM may include a plurality of holes (or openings) OPT1, OPT2, and OPT3 disposed to overlap the light emission areas EA1, EA2, and EA3. For example, the first hole OPT1 may be disposed to overlap the first light emission area EA1, the second hole OPT2 may be disposed to overlap the second light emission area EA2, and the third hole OPT3 may be disposed to overlap the third light emission area EA3. An area or size of each of the holes OPT1, OPT2, and OPT3 may be greater than that of each of the light emission areas EA1, EA2, and EA3 defined by the bank PDL, respectively. Because the holes OPT1, OPT2, and OPT3 of the light shielding layer BM are formed to be greater in size than the light emission areas EA1, EA2, and EA3, light emitted from each of the light emission areas EA1, EA2, and EA3 may be visible to a user even at a side of the display device 10 as well as a front of the display device 10.

The light shielding layer BM may include a light absorbing material. For example, the light shielding layer BM may include an inorganic black pigment or an organic black pigment. The inorganic black pigment may be carbon black, and the organic black pigment may include at least one of lactam black, perylene black, or aniline black but is not limited thereto. The light shielding layer BM may prevent visible light from permeating among the first to third light emission areas EA1, EA2, and EA3 to prevent color mixture, thereby improving color reproduction of the display device 10.

The display device 10 may include a plurality of color filters CF1, CF2, and CF3 disposed on the light emission areas EA1, EA2, and EA3. Each of the plurality of color filters CF1, CF2, and CF3 may be disposed to correspond to each of the light emission areas EA1, EA2, and EA3. For example, the color filters CF1, CF2, and CF3 may be disposed on the light shielding layer BM that includes the plurality of holes OPT1, OPT2, and OPT3 disposed to correspond to the light emission areas EA1, EA2, and EA3.

The color filters CF1, CF2, and CF3 may include a first color filter CF1, a second color filter CF2, and a third color filter CF3, which are disposed to correspond to different light emission areas EA1, EA2, and EA3, respectively. The color filters CF1, CF2, and CF3 may include a colorant, such as a dye or a pigment, which absorbs light of a wavelength range other than light of a specific wavelength range, and may be disposed to correspond to a color of light emitted from each of the light emission areas EA1, EA2, and EA3. For example, the first color filter CF1 may be a red color filter disposed to overlap the first light emission area EA1 for transmitting only the first light of a red color. The second color filter CF2 may be a green color filter disposed to overlap the second light emission area EA2 for transmitting only the second light of a green color. The third color filter CF3 may be a blue color filter disposed to overlap the third light emission area EA3 for transmitting only the third light of a blue color.

The color filters CF1, CF2, and CF3 may be disposed to partially overlap other adjacent color filters CF1, CF2, and CF3. The display device 10 may reduce intensity of reflective light due to external light when the color filters CF1, CF2, and CF3 are disposed to overlap (e.g., to partially overlap) one another. Furthermore, a color of the reflective light due to the external light may be controlled by adjusting layouts, shapes, and areas of the color filters CF1, CF2, and CF3 in a plan view, but the present disclosure is not limited thereto. The plurality of color filters CF1, CF2, and CF3 may be spaced apart from other color filter layers CF1, CF2, and CF3 adjacent thereto on the light shielding layer BM. The color filters CF1, CF2, and CF3 may respectively cover the holes OPT1, OPT2, and OPT3 in the light shielding layer BM and may have an area that is greater than that of the corresponding holes OPT1, OPT2, and OPT3 and spaced apart from the other color filters CF1, CF2, and CF3 on the light shielding layer BM.

The color filters CF1, CF2, and CF3 of the color filter layer CFL may be disposed on the light shielding layer BM. The different color filters CF1, CF2, and CF3 may be disposed to correspond to the different light emission areas EA1, EA2, and EA3 or the opening areas OP1, OP2 and OP3 and the holes OPT1, OPT2, and OPT3 in the light shielding layer BM, respectively. For example, the first color filter CF1 may be disposed to correspond to the first light emission area EA1, the second color filter CF2 may be disposed to correspond to the second light emission area EA2, and the third color filter CF3 may be disposed to correspond to the third light emission area EA3. The first color filter CF1 may be disposed in the first hole OPT1 in the light shielding layer BM, the second color filter CF2 may be disposed in the second hole OPT2 in the light shielding layer BM, and the third color filter CF3 may be disposed in the third hole OPT3 in the light shielding layer BM. Each of the color filters CF1, CF2, and CF3 may be disposed to have an area greater than that of each of the holes OPT1, OPT2, and OPT3 of the light shielding layer BM in a plan view, and a portion of each of the color filters CF1, CF2, and CF3 may be disposed directly on the light shielding layer BM.

An overcoat layer OC may be disposed on the color filters CF1, CF2, and CF3 to planarize upper ends (or upper surfaces) of the color filters CF1, CF2, and CF3. The overcoat layer OC may be a colorless, light-transmissive layer that does not have a color in a visible light band. For example, the overcoat layer OC may include a colorless, light-transmissive organic material, such as an acrylic resin.

A lens array layer LAL may be disposed on the overcoat layer OC. The lens array layer LAL may include a plurality of micro lenses ML1, ML2, and ML3. For example, the lens array layer LAL may include a first micro lens ML1 disposed to correspond to the first light emission area EA1 or the first hole OPT1, a second micro lens ML2 disposed to correspond to the second light emission area EA2 or the second hole OPT2, and a third micro lens ML3 disposed to correspond to the third light emission area EA3 or the third hole OPT3.

A filler FL may be disposed on the lens array layer LAL. The filler FL may be disposed between adjacent micro lenses ML1, ML2, and ML3.

The encapsulation substrate SUB2 may be disposed on the filler FL.

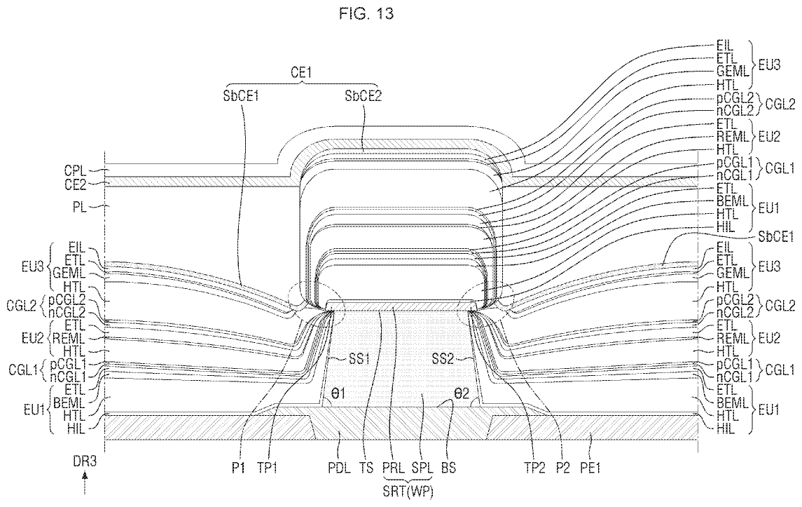

FIG. 13 is a detailed cross-sectional view of a wide width portion WP and a peripheral portion of the separator SRT shown in FIG. 12.

As shown in FIG. 13, the first light emitting unit EU1 may be disposed on the first pixel electrode PE1. The first light emitting unit EU1 may include a hole injection layer HIL, a hole transporting layer HTL, a blue organic light emitting layer BEML, and an electron transporting layer ETL, which are sequentially stacked along (or stacked in) the third direction DR3.

The first charge generation layer CGL1 may be disposed on the first light emitting unit EU1. The first charge generation layer CGL1 may include a first negative charge generation layer nCGL1 and a first positive charge generation layer pCGL1, which are sequentially stacked along the third direction DR3.

The second light emitting unit EU2 may be disposed on the first charge generation layer CGL1. The second light emitting unit EU2 may include a hole transporting layer HTL, a red organic light emitting layer REML, and an electron transporting layer ETL, which are sequentially stacked along the third direction DR3.

The second charge generation layer CGL2 may be disposed on the second light emitting unit EU2. The second charge generation layer CGL2 may include a second negative charge generation layer nCGL2 and a second positive charge generation layer pCGL2, which are sequentially stacked along the third direction DR3.

The third light emitting unit EU3 may be disposed on the second charge generation layer CGL2. The third light emitting unit EU3 may include a hole transporting layer HTL, a green organic light emitting layer GEML, an electron transporting layer ETL, and an electron injection layer EIL, which are sequentially stacked along the third direction DR3.

As shown in FIG. 13, the wide width portion WP of the separator SRT has a first side SS1 and a second side SS2 having a sharp gradient (or a steep slope), and the first tip TP1 and the second tip TP2 are disposed on both sides of the protrusion layer PRL of the wide width portion WP. Therefore, the first light emitting unit EU1 disposed on a left side of the separator SRT, the first light emitting unit EU1 disposed on an upper side of the separator SRT, and the first light emitting unit EU1 disposed on a right side of the separator SRT may be separated from one another. For example, the hole injection layer HIL of the first light emitting unit EU1 may be separated from the separator SRT in a unit of pixel (e.g., per pixel), the hole transporting layer HTL of the first light emitting unit EU1 may be separated from the separator SRT in a unit of pixel, and the blue organic light emitting layer BEML of the first light emitting unit EU1 may be separated from the separator SRT in a unit of pixel. The electron transporting layer ETL of the first light emitting unit EU1 may be separated from the separator SRT in a unit of pixel. Similarly, the second light emitting unit EU2 disposed on the left side of the separator SRT, the second light emitting unit EU2 disposed on the upper side of the separator SRT, and the second light emitting unit EU2 disposed on the right side of the separator SRT may be separated from one another. Similarly, the third light emitting unit EU3 disposed on the left side of the separator SRT, the third light emitting unit EU3 disposed on the upper side of the separator SRT, and the third light emitting unit EU3 disposed on the right side of the separator SRT may be separated from one another.

In addition, as shown in FIG. 13, the first charge generation layer CGL1 disposed on the left side of the separator SRT, the first charge generation layer CGL1 disposed on the upper side of the separator SRT and the first charge generation layer CGL1 disposed on the right side of the separator SRT may be separated from one another. For example, the first negative charge generation layer nCGL1 of the first charge generation layer CGL1 may be separated from the separator SRT in a unit of pixel, and the first positive charge generation layer pCGL1 of the first charge generation layer CGL1 may be separated from the separator SRT in a unit of pixel. Similarly, the second charge generation layer CGL2 disposed on the left side of the separator SRT, the second charge generation layer CGL2 disposed on the upper side of the separator SRT, and the second charge generation layer CGL2 disposed on the right side of the separator SRT may be separated from one another.

As described above, the light emitting units and the charge generation layers, which are disposed with the wide width portion WP of the separator SRT interposed therebetween, may be disconnected. For example, the first light emitting layer EL1 on the first pixel electrode PE1, the second light emitting layer EL2 on the second pixel electrode PE2, and the third light emitting layer EL3 on the third pixel electrode PE3 may be separated from one another at a first point P1 and a second point P2 shown in FIG. 13. Also, the charge generation layers CGL1 and CGL2 on the first pixel electrode PE1, the charge generation layers CGL1 and CGL2 on the second pixel electrode PE2, and the charge generation layers CGL1 and CGL2 on the third pixel electrode PE3 may be separated from one another at the first point P1 and a second point P2 shown in FIG. 13. Therefore, even though a width of the bank PDL in a micro pixel structure is reduced, a current path between adjacent pixels may not be formed. In other words, even when a distance between adjacent pixels in the fine pixel structure is reduced, lateral leakage current between the adjacent pixels may be minimized.

As shown in FIG. 13, in the wide width portion WP, the second sub-common electrode SbCE2 disposed on the upper side of the separator SRT may be disposed at a high position in the third direction DR3 due to a thickness of the separator SRT and a thickness of the first light emitting layer EL1 on the separator SRT. In other words, the second sub-common electrode SbCE2 disposed on the upper side of the separator SRT may be disposed to be higher in the third direction DR3 than the first sub-common electrode SbCE1 disposed on the side of the separator SRT. Therefore, the second sub-common electrode SbCE2 may be in direct contact with the second common electrode CE2 disposed directly on the second sub-common electrode SbCE2. As a result, the second sub-common electrode SbCE2 and the second common electrode CE2 may be electrically connected to each other.

The separator SRT may have a height in a range of about 4000 Å or more. In such an embodiment, the height of the separator SRT may be, for example, a distance (e.g., a distance in the third direction DR3) from the lower surface BS of the support layer SPL to the upper surface of the protrusion layer PRL.

Also, a width w1 of the separator SRT in the wide width portion WP may be in a range of, for example, about 1.0 μm or more.

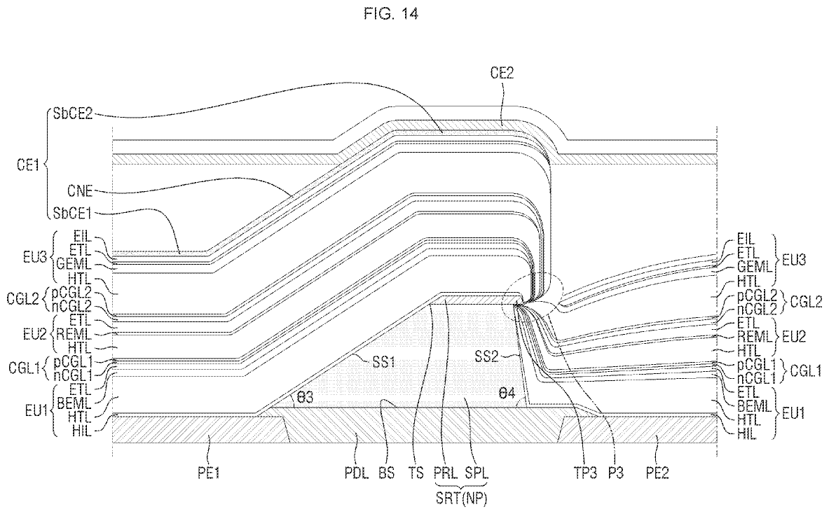

FIG. 14 is a detailed cross-sectional view of a narrow width portion NP and a peripheral portion of the separator shown in FIG. 12.

As shown in FIG. 14, the first light emitting unit EU1 may be disposed on the first pixel electrode PE1. The first light emitting unit EU1 may include a hole injection layer HIL, a hole transporting layer HTL, a blue organic light emitting layer BEML, and an electron transporting layer ETL, which are sequentially stacked along the third direction DR3.

The first charge generation layer CGL1 may be disposed on the first light emitting unit EU1. The first charge generation layer CGL1 may include a first negative charge generation layer nCGL1 and a first positive charge generation layer pCGL1, which are sequentially stacked along the third direction DR3.

The second light emitting unit EU2 may be disposed on the first charge generation layer CGL1. The second light emitting unit EU2 may include a hole transporting layer HTL, a red organic light emitting layer REML, and an electron transporting layer ETL, which are sequentially stacked along the third direction DR3.

The second charge generation layer CGL2 may be disposed on the second light emitting unit EU2. The second charge generation layer CGL2 may include a second negative charge generation layer nCGL2 and a second positive charge generation layer pCGL2, which are sequentially stacked along the third direction DR3.

The third light emitting unit EU3 may be disposed on the second charge generation layer CGL2. The third light emitting unit EU3 may include a hole transporting layer HTL, a green organic light emitting layer GEML, an electron transporting layer ETL, and an electron injection layer EIL, which are sequentially stacked along the third direction DR3.

As shown in FIG. 14, the narrow width portion NP of the separator SRT has a first side SS1 of a gentle gradient (e.g., having a gentle or low slope) and a second side SS2 of a sharp gradient (e.g., having a steep slope), and the third tip TP3 is disposed on one side (e.g., the right side of the protrusion layer PRL) of the protrusion layer PRL of the narrow width portion NP so that the first light emitting unit EU1 disposed on the left side of the separator SRT and the first light emitting unit EU1 disposed on the upper side of the separator SRT are connected to each other, whereas the first light emitting unit EU1 disposed on the left side and the upper side of the separator SRT and the first light emitting unit EU1 disposed on the right side of the separator SRT may be separated from each other. Similarly, the second light emitting unit EU2 disposed on the left side of the separator SRT and the second light emitting unit EU2 disposed on the upper side of the separator SRT are connected to each other, whereas the second light emitting unit EU2 disposed on the left side and the upper side of the separator SRT and the second light emitting unit EU2 disposed on the right side of the separator SRT may be separated from each other. Similarly, the third light emitting unit EU3 disposed on the left side of the separator SRT and the third light emitting unit EU3 disposed on the upper side of the separator SRT are connected to each other, whereas the third light emitting unit EU3 disposed on the left side and the upper side of the separator SRT and the third light emitting unit EU3 disposed on the right side of the separator SRT may be separated from each other. In addition, the first charge generation layer CGL1 disposed on the left side of the separator SRT and the first charge generation layer CGL1 disposed on the upper side of the separator SRT are connected to each other, whereas the first charge generation layer CGL1 disposed on the left side and the upper side of the separator SRT and the first charge generation layer CGL1 disposed on the right side of the separator SRT may be separated from each other. Similarly, the second charge generation layer CGL2 disposed on the left side of the separator SRT and the second charge generation layer CGL2 disposed on the upper side of the separator SRT are connected to each other, whereas the second charge generation layer CGL2 disposed on the left side and the upper side of the separator SRT and the second charge generation layer CGL2 disposed on the right side of the separator SRT may be separated from each other.

As described above, the light emitting units and the charge generation layer, which are disposed with the narrow width portion NP of the separator SRT interposed therebetween may be disconnected. For example, at the point P3 shown in FIG. 14, the first light emitting layer EL1 on the first pixel electrode PE1, the second light emitting layer EL2 on the second pixel electrode PE2, and the third light emitting layer EL3 on the third pixel electrode PE3 may be separated from one another. Also, at the point P3, the charge generation layers CGL1 and CGL2 on the first pixel electrode PE1, the charge generation layers CGL1 and CGL2 on the second pixel electrode PE2, and the charge generation layers CGL1 and CGL2 on the third pixel electrode PE3 may be separated from one another. Therefore, even though the width of the bank PDL in the micro pixel structure is reduced, a current path between adjacent pixels may be prevented from being formed. In other words, even though the distance between the adjacent pixels is reduced in the fine pixel structure, a lateral leakage current between the adjacent pixels may be minimized.

As shown in FIG. 14, the narrow width portion NP of the separator SRT has a first side SS1 of a gentle gradient, and the third tip TP3 is not disposed at an end portion of the protrusion layer PRL adjacent to the first side SS1 so that the first sub-common electrode SbCE1 on the first pixel electrode PE1, the connection electrode CNE on the first side SS1, and the second sub-common electrode SbCE2 on the protrusion layer PRL may be connected to one another without being separated from one another. In other words, the first sub-common electrode SbCE1 and the second sub-common electrode SbCE2 may be connected to each other through the connection electrode CNE at the narrow width portion NP of the separator SRT. In addition, in the narrow width portion NP, the second sub-common electrode SbCE2 disposed on the upper side of the separator SRT may be disposed at a higher position in the third direction DR3 by the thickness of the separator SRT and the thickness of the first light emitting layer EL1 on the separator SRT. In other words, the second sub-common electrode SbCE2 disposed on the upper surface of the separator SRT may be disposed to be higher than the first sub-common electrode SbCE1 disposed on the side of the separator SRT. Therefore, the second sub-common electrode SbCE2 may be in direct contact with the second common electrode CE2 directly disposed thereon. As a result, the second sub-common electrode SbCE2 and the second common electrode CE2 may be electrically connected to each other. In other words, the first common electrode CE1 and the second common electrode CE2 may be electrically connected to each other. Because the second common electrode CE2 has a shape of a surface electrode having a wide area, a voltage drop (e.g., IR drop) of a common voltage provided to the common electrode CE may be reduced or minimized.

As described above, according to embodiments of the present disclosure, because the separator SRT has at least one narrow width portion NP, the light emitting layer and the charge generation layer are separated from each other in each pixel while the common electrode CE may not be separated. Therefore, the lateral leakage current is reduced or minimized and the voltage drop of the common voltage is also reduced or minimized.

The separator SRT may have a height in a range of about 4000 Å or more. In such an embodiment, the height of the separator SRT may be, for example, a distance (e.g., a distance in the third direction DR3) from the lower surface BS of the support layer SPL to the upper surface of the protrusion layer PRL.

The width w2 of the separator SRT in the wide width portion WP may be in range of, for example, about 1.0 μm or more. In such an embodiment, the width w2 of the narrow width portion NP may be smaller than the width w1 of the wide width portion WP.

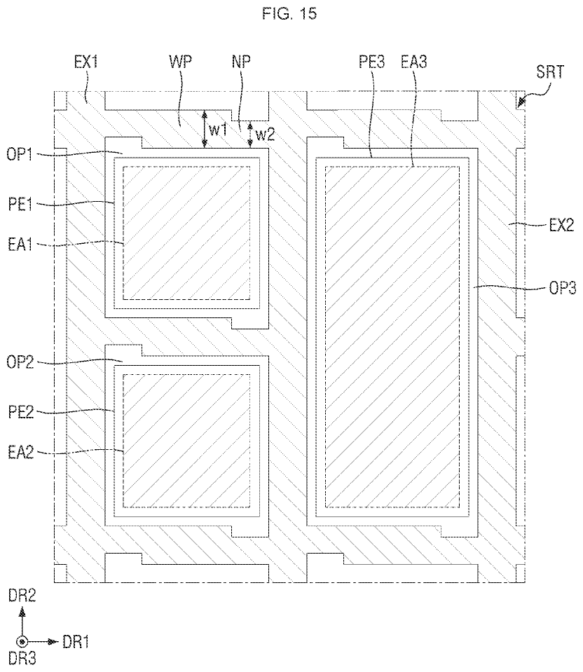

FIG. 15 is a plan view of a pixel electrode and a separator SRT of the display device 10 according to another embodiment.

The display device 10 shown in FIG. 15 is different from that shown in FIG. 5 in that the arrangement positions of the narrow width portion NP of the separator SRT are different from each other, and thus, the following description will focus on this difference.

As shown in FIG. 15, the narrow width portion NP may be disposed at an edge of the first extension portion EX1 and an edge of the second extension portion EX2.

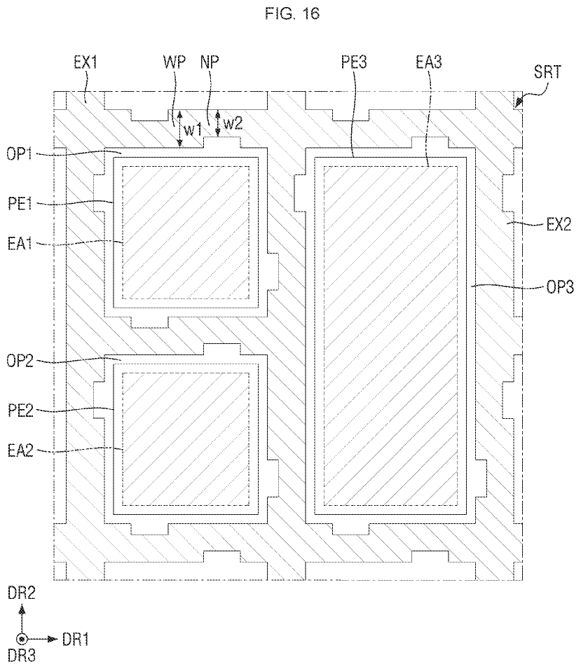

FIG. 16 is a plan view of a pixel electrode and a separator SRT of the display device 10 according to another embodiment.

The display device shown in FIG. 16 is different from that shown in FIG. 5 in that the number of narrow width portions NP of the separator SRT is different from that shown in FIG. 5, and thus, the following description will focus on this difference.

As shown in FIG. 16, four or more narrow width portions NP may be disposed in one opening area. For example, one narrow width portion NP may be disposed on the upper side, the lower side, the left side, and the right side of the first opening area OP1, respectively, so that a total of four narrow width portions NP may be disposed in (or around) the first opening area OP1.

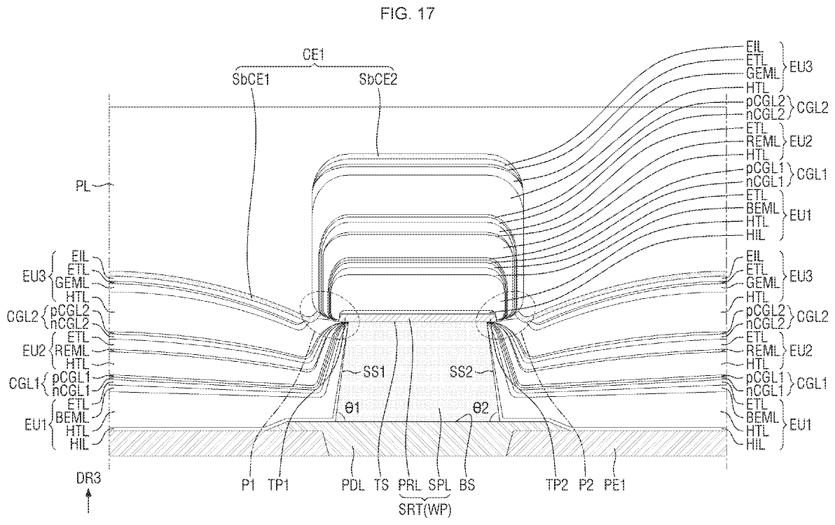

FIGS. 17 to 20 are cross-sectional views illustrating steps of a method for fabricating a display device according to an embodiment.

First, as shown in FIG. 17, a pixel electrode PE1, a bank PDL, and a separator SRT may be formed on a base substrate SUB1. The separator SRT may have a wide width portion WP and a narrow width portion NP. Subsequently, a first light emitting unit EU1, a first charge generation layer CGL1, a second light emitting unit EU2, a second charge generation layer CGL2, and a third light emitting unit EU3 may be sequentially stacked on the separator SRT. Then, a first common electrode CE1 may be formed on the third light emitting unit EU3. The first light emitting unit EU1, the first charge generation layer CGL1, the second light emitting unit EU2, the second charge generation layer CGL2, the third light emitting unit EU3, and the first common electrode CE1 may be separated for each pixel (e.g., on a per pixel basis) by the separator SRT. For example, the first common electrode CE1 may be divided into a first sub-common electrode SbCE1 and a second sub-common electrode SbCE2 by the wide width portion WP of the separator SRT. The first sub-common electrode SbCE1 and the second sub-common electrode SbCE2 of the first common electrode CE1 may be connected to each other by the connection electrode CNE at the narrow width portion NP of the separator SRT. Afterwards, a planarization layer PL may be formed on the entire surface of the base substrate SUB1 including the first common electrode CE1. The planarization layer PL may cover all portions of the first common electrode CE1.

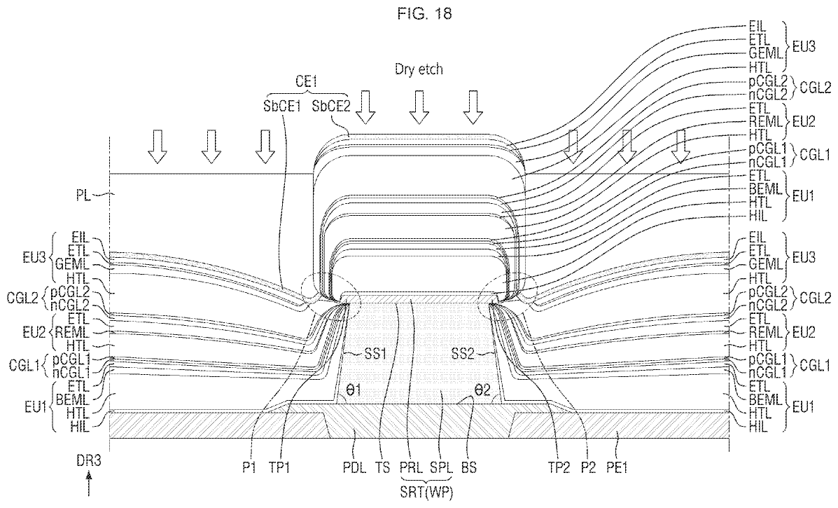

Then, as shown in FIG. 18, a portion of the planarization layer PL may be removed. For example, a portion of the planarization layer PL may be removed by dry etching so that a thickness of the planarization layer PL may be reduced. As a portion of the planarization layer PL is removed, a portion of the second sub-common electrode SbCE2 on the separator SRT may be exposed. For example, the second sub-common electrode SbCE2 on the protrusion layer PRL included in the wide width portion WP of the separator SRT and the second sub-common electrode SbCE2 on the protrusion layer PRL included in the narrow width portion NP of the separator SRT may be exposed to the outside. The etching process for the planarization layer PL may be performed until the second sub-common electrode SbCE2 is exposed.

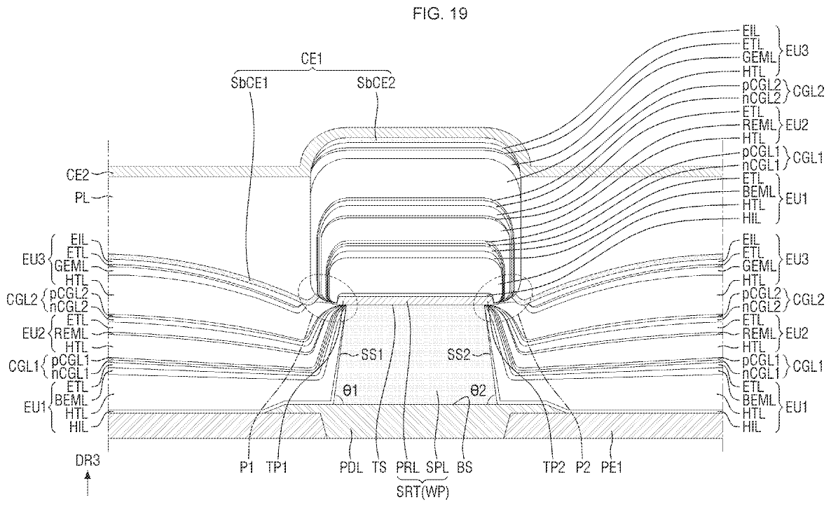

Then, as shown in FIG. 19, the second common electrode CE2 may be formed on the entire surface of the base substrate SUB1 including the planarization layer PL and the second sub-common electrode SbCE2. The second common electrode CE2 may be in contact with the second sub-common electrode SbCE2 that is not covered by (e.g., is exposed through) the planarization layer PL. Therefore, the second common electrode CE2 and the second sub-common electrode SbCE2 may be electrically connected to each other, and the second common electrode CE2 and the first common electrode CE1 may be electrically connected to each other.

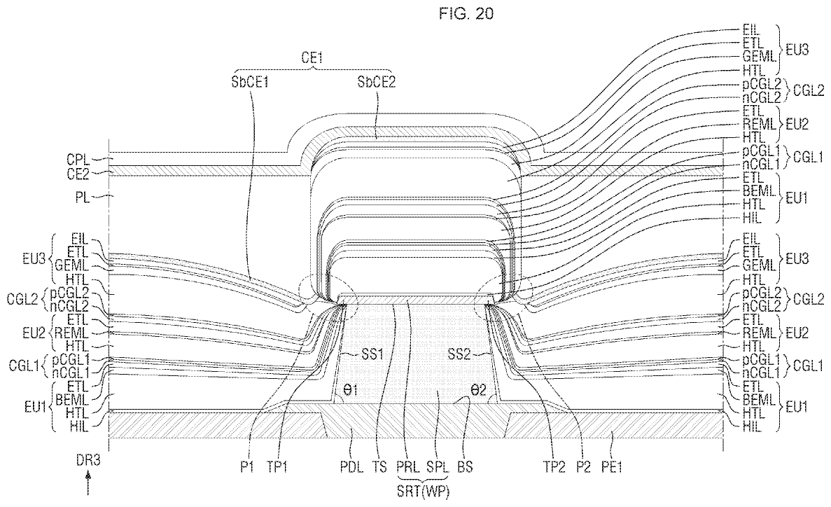

Next, as shown in FIG. 20, a capping layer CPL may be formed on the entire surface of the base substrate SUB1 including the second common electrode CE2.

What is claimed is:

1. A display device comprising:
a pixel electrode;
a bank on the pixel electrode; and
a separator on the bank, the separator having a wide width portion having a first tip and a second tip at both sides and a narrow width portion having a third tip on one side.

2. The display device of claim 1, wherein a first angle between a lower surface of the wide width portion and a first side of the wide width portion is the same as or different from a second angle between the lower surface of the wide width portion and a second side of the wide width portion.

3. The display device of claim 2, wherein each of the first angle and the second angle is an acute angle.

4. The display device of claim 2, wherein a third angle between a lower surface of the narrow width portion and a first side of the narrow width portion is different from a fourth angle between the lower surface of the narrow width portion and a second side of the narrow width portion.

5. The display device of claim 4, wherein the first side from among the first and second sides of the narrow width portion is farther from the third tip than the second side of the narrow width portion is.

6. The display device of claim 5, wherein the third angle is smaller than the fourth angle.

7. The display device of claim 5, wherein the third angle is smaller than the at least one of first angle or the second angle.

8. The display device of claim 5, wherein the fourth angle is the same as at least one of the first angle or the second angle.

9. The display device of claim 4, wherein each of the third angle and the fourth angle is an acute angle.

10. The display device of claim 1, wherein the separator comprises:
a support layer on the bank; and
a protrusion layer on the support layer.

11. The display device of claim 10, wherein an upper surface of the support layer at the narrow width portion is smaller than an upper surface of the support layer at the wide width portion.

12. The display device of claim 10, wherein the protrusion layer at the narrow width portion is smaller than the protrusion layer at the wide width portion.

13. The display device of claim 1, further comprising:
a light emitting layer on the pixel electrode; and
a common electrode on the light emitting layer.

14. The display device of claim 13, wherein the light emitting layer comprises a plurality of light emitting units configured to emit light of different colors.

15. The display device of claim 14, wherein the light emitting layer comprises:
a first light emitting unit on the pixel electrode and configured to emit light of a first color;
a second light emitting unit on the first light emitting unit and configured to emit light of a second color; and
a third light emitting unit on the second light emitting unit and configured to emit light of a third color.

16. The display device of claim 13, wherein the common electrode comprises:
a first common electrode on the light emitting layer; and
a second common electrode on the first common electrode.

17. The display device of claim 16, wherein the first common electrode comprises:
a first sub-common electrode on a light emission area of the pixel electrode; and
a second sub-common electrode on the separator.

18. The display device of claim 17, wherein the first common electrode further comprises a connection electrode corresponding to the narrow width portion and connecting the first sub-common electrode with the second sub-common electrode.

19. The display device of claim 18, wherein the second common electrode is connected to the second sub-common electrode.

20. The display device of claim 18, further comprising a planarization layer between the first sub-common electrode and the second common electrode and between the connection electrode and the second common electrode.
